(19) United States
(12) Patent Application Publication
(10) Pub. No.: US 2021/0258522 A1
(43) Pub. Date: Aug. 19, 2021

(54) CAMERA SYSTEM WITH COMPLEMENTARY PIXLET STRUCTURE

(71) Applicant: DEXELION INC., Yuseong-gu (KR)

(72) Inventors: Chong Min KYUNG, Yuseong-gu (KR); Seung Hyuk CHANG, Yuseong-gu (KR); Hyun Sang PARK, Yuseong-gu (KR); Jong Ho PARK, Yuseong-gu (KR); Sang Jin LEE, Yuseong-gu (KR)

(21) Appl. No.: 17/088,924

(22) Filed: Nov. 4, 2020

(30) Foreign Application Priority Data
Feb. 14, 2020 (KR) 10-2020-0018176

(51) Int. Cl. H04N 5/369; H04N 5/3745; H04N 9/04; H04N 5/357; G06T 7/55

(52) U.S. Cl. CPC H04N 5/36965; H04N 5/3745; H04N 9/0451; G06T 2207/20221; G06T 7/55; G06T 2207/10024; H04N 5/357

(57) ABSTRACT

A camera system with a complementary pixlet structure and a method of operating the same are provided. According to an embodiment, the camera system includes an image sensor that includes two pixels, each of the two pixels including a deflected small pixlet deflected in one direction based on a pixel center and a large pixlet disposed adjacent to the deflected small pixlet, each pixlet including a photodiode converting an optical signal to an electric signal, and the deflected small pixlets of the two pixels being arranged to be symmetrical to each other with respect to each of the pixel centers within each of the two pixels, respectively, and a depth calculator that receives images acquired from the deflected small pixlets of the two pixels and calculates a depth between the image sensor and an object using a parallax between the images.

### CROSS-REFERENCE TO RELATED APPLICATIONS

A claim for priority under 35 U.S.C. § 119 is made to Korean Patent Application No. 10-2020-0018176 filed on Feb. 14, 2020, in the Korean Intellectual Property Office, the entire contents of which are hereby incorporated by reference.

### BACKGROUND

Embodiments of the inventive concept described herein relate to an electronic device, and more particularly, relate to a memory system.

An existing camera system includes an image sensor having one photodiode disposed within one pixel below a microlens to obtain a general image by processing light rays having at least one wavelength but not to perform an additional application function-estimation of a depth to an object.

Therefore, for performing the above-described application function in the existing camera system, two or more cameras are provided in the camera system and utilized or an additional aperture distinguished from a basic aperture in the camera system including a single camera are provided.

Accordingly, the following embodiments provide a camera system including an image sensor with a complementary pixlet structure, in which two photodiodes (hereinafter, a term “pixlet” is used as a component corresponding to each of the two photodiodes included in one pixel) are implemented in one pixel, thereby suggesting a technique capable of estimating a depth to an object in a single camera system.

### SUMMARY

Embodiments of the inventive concept provide an image sensor with a complementary pixlet structure, in which two pixlets are implemented in one pixel, to enable estimation of a depth to an object in a single camera system.

In detail, embodiments provide a technique for implementing an image sensor with a structure including two pixels, each of which includes a deflected small pixlet deflected in one direction based on a pixel center and a large pixlet disposed adjacent to the deflected small pixlet, each pixlet including a photodiode converting an optical signal into an electrical signal and the deflected small pixlets of the two pixels being arranged to be symmetrical to each other with respect to each pixel center within each of the two pixels, and thus a camera system including the above-described image sensor calculates a depth between the image sensor and an object using a parallax between images acquired from the deflected small pixlets of the two pixels.

Here, embodiments provide a camera system regularly using a pixlets for calculating a depth within two pixels, to simplify a depth calculating algorithm and reduce work complexity, to reduce depth calculation time consumption and secure real-time, to simplify circuit configuration, and to ensure consistent depth resolution.

According to an exemplary embodiment, a camera system with a complementary pixlet structure includes an image sensor that includes two pixels, each of the two pixels including a deflected small pixlet deflected in one direction based on a pixel center and a large pixlet disposed adjacent to the deflected small pixlet, each pixlet including a photodiode converting an optical signal to an electric signal, and the deflected small pixlets of the two pixels being arranged to be symmetrical to each other with respect to each of the pixel centers within each of the two pixels, respectively, and a depth calculator that receives images acquired from the deflected small pixlets of the two pixels and calculates a depth between the image sensor and an object using a parallax between the images.

According to an exemplary embodiment, a method of operating a camera system including an image sensor with a complimentary pixlet structure and a depth calculator includes inputting optical signals to two pixels, each of the two pixels including a deflected small pixlet deflected in one direction based on a pixel center and a large pixlet disposed adjacent to the deflected small pixlet, each pixlet including a photodiode converting an optical signal to an electric signal, and the deflected small pixlets of the two pixels being arranged to be symmetrical to each other with respect to each of pixel centers within the two pixels, respectively, includes processing, at the image sensor, the optical signals through the deflected small pixlets of the two pixels to obtain images and calculating, the depth calculator, a depth between the image sensor and an object using a parallax between the images input from the image sensor.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a diagram illustrating a principle of calculating a depth to an object from a camera system according to an embodiment;

FIGS. 2A to 2B are diagrams illustrating schematic structures of an image sensor included in a camera system according to an embodiment;

FIG. 2C is a diagram illustrating a simulation result for a distance at which a deflected small pixlet is offset in a camera system according to an embodiment;

FIG. 3 is a flowchart illustrating a method of operating a camera system according to an embodiment; and

FIG. 4 is a flowchart illustrating a method of operating a camera system according to another embodiment.

### DETAILED DESCRIPTION

Hereinafter, embodiments of the inventive concept will be described in detail with reference to the accompanying drawings. However, the inventive concept is not confined or limited by the embodiments. In addition, the same reference numerals shown in each drawing denote the same member.

A depth (hereinafter, “depth” refers to a distance between an object and an image sensor) of each of pixels included in a 2D image should be calculated to obtain a 3D image to which the depth is applied. Here, the conventional methods of calculating the depth of each pixel included in the 2D image include a time of flight (TOF) method which irradiates a laser to an object to be photographed and measures time the light returns, a depth from stereo method that calculates a depth using a parallax between images acquired from two or more camera systems, a method (a parallax difference method using an aperture) which processes an optical signal passing through each of a plurality of apertures formed in a single optical system to calculate a depth using a parallax between acquired images in a single camera system, and a method which processes an optical signal passing through each of a plurality of apertures formed in a single optical system to calculate a depth using a blur change between acquired images in a single camera system.

Accordingly, following embodiments propose an image sensor with a complementary pixlet structure, in which two pixels are implemented in one pixel, to enable estimation of a depth to an object in a single camera system. Hereinafter, a pixlet disposed in a pixel may be a component including a photodiode converting an optical signal into an electrical signal and two pixlets with different light receiving areas from each other may be provided in the pixel. In addition, hereinafter, the complementary pixlet structure means a structure in which, in the pixel including a first pixlet and a second pixlet, when an area of the first pixlet is given in the pixel, an area of the second pixlet is capable of being calculated by subtracting the first pixlet from the pixel area. However, the inventive concept is not confined or limited thereto, and when the pixel includes a deep trench isolation (DTI) for reducing interference between the first pixlet and second pixlet, the complementary pixlet structure means a structure in which when an area of the first pixlet is given in the pixel, an area of the second pixlet is capable of being calculated by subtracting the area of the first pixlet from an area excluding the DTI area from the pixel area.

In detail, embodiments suggest technique in which an image sensor with a structure including two pixels, each of which includes a deflected small pixlet deflected in one direction based on a pixel center and a large pixlet disposed adjacent to the deflected small pixlet—the deflected small pixlets of the two pixels are arranged to be symmetrical to each other with respect to each pixel center within each of the two pixels—is configured, and thus the camera system including the above-described image sensor calculates a depth between the image sensor and an object using a parallax between images acquired from the deflected small pixlets of the two pixels. The above-described depth calculation method is based on offset aperture (OA).

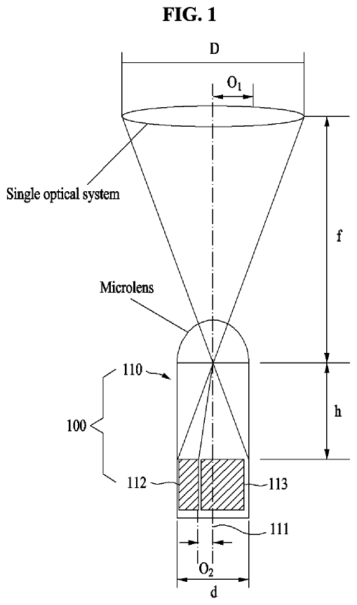

FIG. 1 is a diagram illustrating a principle of calculating a depth to an object from a camera system according to an embodiment.

Referring to FIG. 1, according to an embodiment, an image sensor 100 with a complementary pixlet structure may include a deflected small pixlet 112 deflected in one direction with respect to a pixel center 111 in a pixel 110 and a large pixlet 113 disposed adjacent to the deflected small pixlet 112.

Here, the deflected small pixlet 112 (hereinafter, a left-deflected small pixlet) of the pixel 110 may be deflected in a left direction with respect to the pixel center 111 of the pixel 110, have a light-receiving area occupying only a part of a left area of the pixel 110 with respect to the pixel center 111, and be formed by offsetting a specific distance or more to the left from the pixel center 111 of the pixel 110.

Accordingly, an optical signal introduced through a single optical system disposed on the pixel 110 may be incident on the left-deflected small pixlet 112 of the pixel 110, through a principle as shown in the drawing, and thus O2, which is a distance at which one edge of the left-deflected small pixlet 112 is offset from the pixel center 111 of the pixel 110, has a proportional relationship with O1, which, when an aperture is formed on the single optical system, is a distance at which the aperture is offset from a center of the single optical system (the same as the center 111 of the pixel 110). In the drawing, “D” denotes a diameter of the single optical system, “f” denotes a focal length, “d” denotes a width of the pixel 110, and “h” denotes a distance from the microlens of the pixel 110 to the pixel center 111 of the pixel 110.

Therefore, the same principle as the aperture formed on the single optical system to be offset from a center of the single optical system (the same as the pixel center 111 of the pixel 110) may be applied to the left-deflected small pixlet 112 formed to be offset from the pixel center 111 of the pixel 110, and thus the camera system including the image sensor 100 may calculate a depth between an object and the image sensor 100 using an offset aperture (OA)-based depth calculation method.

As described above, as the offset aperture (OA)-based depth calculation method is applied, the principle of calculating the depth of the camera system including the image sensor 100 to which the complementary pixlet structure is applied may be descried as a case based on a parallax difference method in the OA structure, but it may be not confined or limited thereto, and the principle may be based on various methods for calculating the depth in the image using two images forming the parallax.

In addition, it may be described that the image sensor 100 includes one pixel 110, but may be not confined or limited thereto, and a case including two or more pixels to which the complementary pixlet structure is applied may also calculate the depth between the image sensor 100 and the object based on the above-described principle.

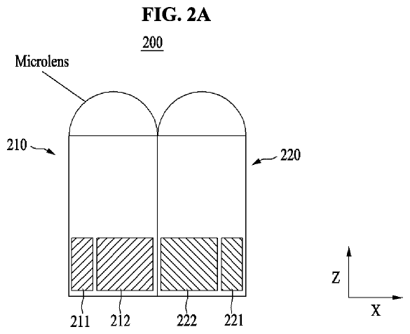

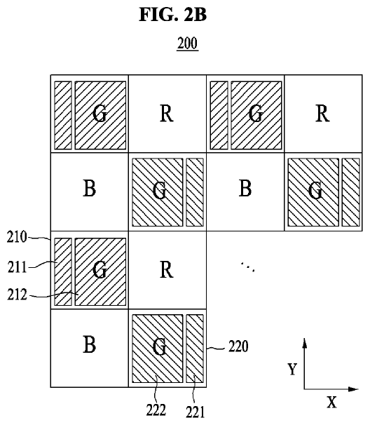

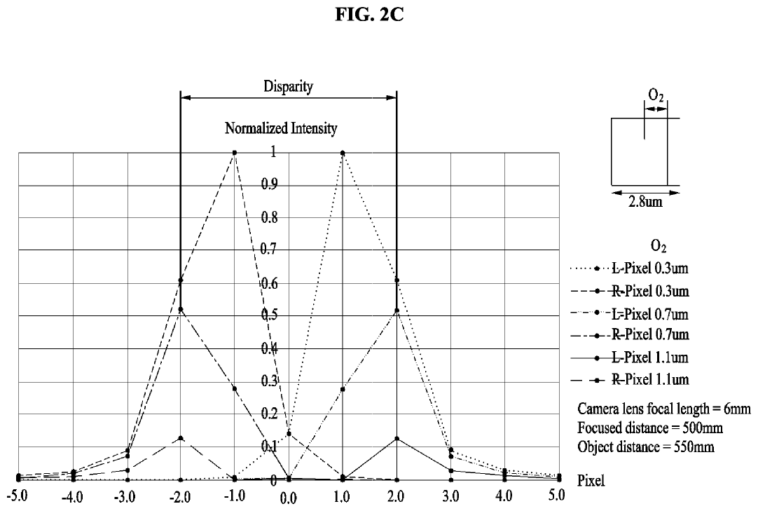

FIGS. 2A to 2B are diagrams illustrating schematic structures of an image sensor included in a camera system according to an embodiment and FIG. 2C is a diagram illustrating a simulation result for a distance at which a deflected small pixlet is offset in a camera system according to an embodiment. In detail, FIG. 2A is a cross-sectional view showing a schematic structure of the image sensor included in the camera system according to an embodiment, and FIG. 2B is a plan view showing a schematic structure of the image sensor included in the camera system according to the embodiment. In addition, FIG. 2C shows luminous intensity distribution at each position of a pixel array for an image of an object (a point light source) deviated from of a focused position. A position difference between a left-deflected small pixlet and a right-deflected small pixlet having maximum luminance becomes a parallax of the object. Simulation conditions are 2.8 um pixel size, a camera with a lens focused 500 mm away from the camera (a focal length of the lens of 6 mm), and a depth of 550 mm from the object.

Referring to FIGS. 2A to 2B, a camera system according to an embodiment may include an image sensor 200 and a depth calculator (not shown). Hereinafter, the camera system may be not confined or limited to including only the image sensor 200 and the depth calculator, and may further include a single optical system (not shown). In addition, hereinafter, it will be described that the camera system performs a calculating operation of the depth between the object and the image sensor 200, which means that the depth calculator included in the camera system performs the calculating operation.

The image sensor 200 includes two pixels 210 and 220. The two pixels 210 and 220 include deflected small pixlets 211 and 221 deflected in one direction with respect to the pixel center of each of the pixels, respectively, and large pixlets 212 and 222 disposed adjacent to the deflected small pixlets 211 and 221, respectively. Hereinafter, the two pixels 210 and 220 to which the complementary pixlet structure is applied may be limited to pixels used for the depth calculation in the image sensor (e.g., a G-pixel in a case of an RGBG image sensor as shown in the drawing and a W-pixel in a case of an RGBW image sensor). However, the inventive concept may be not confined or limited thereto, and may be all pixels constituting the image sensor (e.g., an R-pixel, the G-pixel, and a B-pixel).

Here, the deflected small pixlets 211 and 221 of the two pixels 210 and 220 are disposed to be symmetrical to each other with respect to each pixel center within each of the two pixels 210 and 220, respectively. For example, the deflected small pixlet 211 (hereinafter, a left-deflected small pixlet 211) of the first pixel 210 may be deflected in a left direction with respect to the pixel center of the first pixel 210, have a light-receiving area occupying only a part of a left area with respect to the pixel center, and be formed by offsetting a specific distance or more to the left from the pixel center of the first pixel 210. In addition, the deflected small pixlet 221 (hereinafter, a right-deflected small pixlet 221) of the second pixel 220 may be deflected in a right direction with respect to the pixel center of the second pixel 220, have a light-receiving area occupying only a part of a right area with respect to the pixel center, and be formed by offsetting a specific distance or more to the right from the pixel center of the second pixel 220.

That is, the two pixels 210 and 220 of the image sensor 200 according to an embodiment include the left-deflected small pixlet 211 and the right-deflected small pixlet 221, which are used for the depth calculation.

Here, the deflected small pixlets 211 and 221 of the two pixels 210 and 220 may be disposed to maximize a distance apart from each other within the two pixels 210 and 220, respectively. This is because the depth calculation below is performed based on the images acquired from the deflected small pixlets 211 and 221 of the two pixels 210 and 220, and consistently securing depth resolution as the parallax between the images increases in the depth calculation.

Here, a distance, at which the deflected small pixlets 211 and 221 of the two pixels 210 and 220 are separated from each other, is related to a size and arrangement of each of the deflected small pixlets 211 and 221 of the two pixels 210 and 220. The size and arrangement of each of the deflected small pixlets 211 and 221 of the two pixels 210 and 220 is related to an offset distance of each of the deflected small pixlets 211 and 221 of the two pixels 210 and 220 from each pixel center of each of the two pixels 210 and 220, respectively.

Thus, maximizing the distance, at which the deflected small pixlets 211 and 221 of the two pixels 210 and 220 are separated from each other may equivalent to maximizing the distance at which each of the deflected small pixlets 211 and 221 of the two pixels 210 and 220 is offset from the each pixel center of each of the two pixels 210 and 220, respectively, thereby allowing each of the deflected small pixlets 211 and 221 of each of the two pixels 210 and 220 to be formed to maximize the distance offset from the each pixel center of each of the two pixels 210 and 220, respectively.

In particular, the distance, in which each of the deflected small pixlets 211 and 221 of each of the two pixels 210 and 220 is offset from each pixel center of each of the two pixels 210 and 220, respectively, may be determined to maximize the parallax between the images acquired from the deflected small pixlets 211 and 221 of the two pixels 210 and 220, respectively, assuming that sensitivity of sensing optical signals in the deflected small pixlets 211 and 221 of the two pixels 210 and 220 is guaranteed to be greater than or equal to a predetermined level.

Referring to FIG. 1 in this regard, O2, which is an offset distance of the deflected small pixlets 211 and 221 of each of the two pixels 210 and 220 from each pixel center of each of the two pixels 210 and 220 has a proportional relationship to O1, which is a distance offset from a center of the single optical system. That is, O1 and O2 may be expressed as Equation 1 below.

$$\frac{{O}_{2}}{h} = \frac{{O}_{1}}{n f} \qquad < Equation 1 >$$

In Equation 1, “n” denotes a refractive index of a microlens of each of the two pixels 210 and 220, “f” denotes a focal length (a distance from a center of the image sensor 200 to the single optical system), and “h” denotes a distance from the microlens of each of the two pixels 210 and 220 to each center of each of the two pixels 210 and 220.

Meanwhile, due to experimental technique, when O₁, which is the distance offset from the center of the single optical system is in a range as Equation 2 below, assuming that sensitivity of sensing the optical signals in the deflected small pixlets 211 and 221 of the two pixels 210 and 220 is guaranteed to be greater than or equal to the predetermined level, it is shown that the parallax between the images acquired from the deflected small pixlets 211 and 221 of the two pixels 210 and 220 is maximized.

a·D≤O₁≤b·D <Equation 2>

In Equation 2, “D” denotes a diameter of the single optical system, “a” denotes a constant having a value of 0.2 or more, and “b” denotes a constant having a value of 0.47 or less.

Accordingly, Equation 1 may be expressed as Equation 3 below by Equation 2. Here, as illustrated in Equation 3, the offset distance of each the deflected small pixlets 211 and 221 of each of the two pixels 210 and 220 from the pixel center of each of the two pixels 210 and 220 may be determined based on the refractive index of the microlens of each of the two pixels 210 and 220, the distance from the center of the image sensor 200 to the single optical system, the distance from the microlens of each of the two pixels 210 and 220 to each center of each of the two pixels 210 and 220, and the diameter of the single optical system, to maximize the parallax between the images acquired from the deflected small pixlets 211 and 221 of the two pixels 210 and 220, assuming that the sensitivity of sensing the optical signals in the deflected small pixlets 211 and 221 of the two pixels 210 and 220 is guaranteed to be greater than or equal to the predetermined level.

$$a \frac{h D}{n f} \leq {O}_{2} \leq b \frac{h D}{n f} \qquad < Equation 3 >$$

“a” denotes a constant having a value of 0.2 or more, and “b” denotes a constant having a value of 0.47 or less, and Equation 3 may be expressed as Equation 4 below.

$$0.2 \frac{h D}{n f} \leq {O}_{2} \leq 0.47 \frac{h D}{n f} \qquad < Equation 4 >$$

In an embodiment, when “f” is 1.4D, “n” is 1.4, “h” is 2.9 um, and the pixel size is 2.8 um, O₂ is calculated using Equation 4 above to have a range of 0.3 um≤O₂≤0.7 um. In this regard, referring to FIG. 2C, when the offset distance of each of the deflected small pixlets 211 and 221 of the two pixels 210 and 220 from each of the centers of the each of the two pixels 210 and 220 satisfies the range of Equation 4, it may be seen that when an appropriate parallax is secured, a depth is obtained. That is, when O2 is 0.3 um, a depth is obtained as 2 pixels or when O2 is 0.7 um, a depth is obtained as 4 pixels. In O2 smaller than 0.3 um, the parallax is too small to obtain depth information and in O2 larger than 0.7 um, it is impossible to secure the appropriate parallax due to the small amount of light incident.

Depending on the structure of the deflected small pixlets 211 and 221, the large pixlets 212 and 222 of the two pixels 210 and 220 may be symmetrical to each other within the two pixels and arranged adjacent to each other. For example, the large pixlet 212 of the first pixel 210 may have a light-receiving area occupying an entire right area and a part of the left area with respect to the pixel center of the first pixel 210 and be formed to be offset by a specific distance or more from the pixel center of the first pixel 210. The large pixlet 222 of the second pixel 220 may have a light-receiving area occupying an entire left area and a part of the right area with respect to the pixel center of the second pixel 220 and be formed to be offset by a specific depth or more from the pixel center of the second pixel 220.

Thus, the camera system including the image sensor 200 may calculate the depth from the image sensor 200 to the object, based on the OA-based depth calculation method described with reference to FIG. 1, using the parallax between the images (the image acquired from the left-deflected small pixlet 211 of the first pixel 210 and the image acquired from the right-deflected small pixlet 221 of the second pixel 220). In detail, the image acquired from the left-deflected small pixlet 211 of the first pixel 210 and the image acquired from the right-deflected small pixlet 221 of the second pixel 220, which have the above-described structure may be input to the depth calculator (not shown) included in the camera system. In addition, in response to the input images, the depth calculator may calculate the depth to the object from the image sensor 200 using the parallax between the image acquired from the left-deflected small pixlet 211 of the first pixel 210 and the image acquired from the right-deflected small pixlet 221 of the second pixel 220.

Here, the images (the image acquired from the left-deflected small pixlet 211 and the image acquired from the right-deflected small pixlet 221) input to the depth calculator may be not simultaneously input, but may be multiplexed by pixel unit to be input. Accordingly, the camera system may include a single processing device for removing the noise of the image, to sequentially process the multiplexed images. Here, the depth calculator may not perform image rectification for projecting the images into a common image plane.

In particular, the camera system including the image sensor 200 may regularly use the pixlets 211 and 221 for the depth calculating within the two pixels 210 and 220 to simplify a depth calculating algorithm and reduce work complexity, to reduce depth calculation time consumption and secure real-time, to simplify circuit configuration, and to ensure consistent depth resolution. Accordingly, the camera system including the image sensor 200 may be useful in an autonomous vehicle or various real-time depth measurement applications in which the consistency of depth resolution and real time are important.

Here, the camera system including the image sensor 200 may use two pixlets 212 and 222 for functions (e.g., color image formation and acquisition) other than the depth calculation, in addition to the pixlets 211 and 221 for the depth calculation, within the pixels 210 and 220. For example, the image sensor 200 may form a color image based on the images acquired from the large pixlets 212 and 222 of the two pixels 210 and 220. In detail, the camera system including the image sensor 200 may merge the images acquired from the large pixlets 212 and 222 and the images acquired from the deflected small pixlets 211 and 221, of the two pixels 210 and 220, to form the color image.

In the above-described camera system including the image sensor 200, the pixlets 211 and 221 using for the depth calculation and the pixlets 212 and 222 for the functions other than the depth calculation, within the two pixels 210 and 220, may be differently set, to simplify an algorithm for the depth calculation and an algorithm for the functions other than the depth calculation and to secure real-time of the depth calculation and other functions, respectively.

Thus, the pixlets 211 and 221 using for the depth calculation and the pixlets 212 and 222 for the functions other than the depth calculation may be different, and therefore each of the pixlets 211, 212, 221, and 222 of the two pixels 210 and 220 may be a complimentary pixlet in which each function is complementary in terms of color image acquisition and depth calculation functions.

The image sensor 200 having the structure described above may further include an additional component. As an example, a mask (not shown), which blocks peripheral rays of bundle of rays flowing into the deflected small pixlets 211 and 221 of the two pixels 210 and 220 and introduces only central rays, may be disposed on each of the deflected small pixlets 211 and 221 of each of the two pixels 210 and 220. The images acquired from the deflected small pixlets 211 and 221 of the two pixels 210 and 220 using the mask may have depth greater than images acquired when introducing the periphery rays of the bundle of rays. As another example, a deep trench isolation (DTI) may be formed in each of the two pixels 210 and 220 to reduce interference between the deflected small pixlets 211 and 221 and the large pixels 212 and 222. Here, the DTI may be formed between each of the deflected small pixlets 211 and 221 and each of the large pixels 212 and 222, respectively.

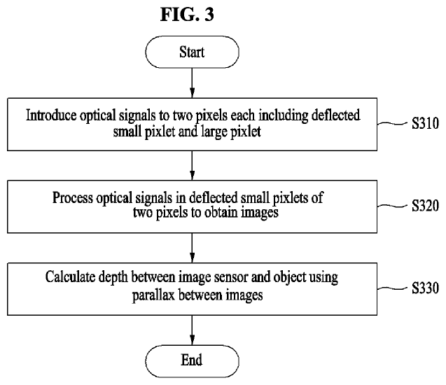

FIG. 3 is a flowchart illustrating a method of operating a camera system according to an embodiment. The method of operating the camera system described below may be performed by the camera system including the image sensor and the depth calculator having the structure described above with reference to FIG. 2A, 2B.

Referring to FIG. 3, the image sensor introduces optical signals into the two pixels each of which includes a deflected small pixlet deflected in one direction based on a pixel center and a large pixlet disposed adjacent to the deflected small pixlet—the deflected small pixlets of the two pixels are arranged to be symmetrical to each other with respect to each pixel center within each of the two pixels—through S310. For example, the image sensor may introduce the optical signals to the left-deflected small pixlet of the first pixel and the right-deflected small pixlet of the second pixel, respectively.

Here, the deflected small pixlets of the two pixels may be disposed within the two pixels, respectively, to maximize the distance apart from each other, and in particular, the offset distance of each of the deflected small pixlets of each of the two pixels from the pixel center of each of the pixels may be determined to maximize the parallax between the images acquired by the deflected small pixlets of the two pixels, assuming that the sensitivity of sensing the optical signals from the deflected small pixlets of each of the two pixels is guaranteed to be greater than or equal to the predetermined level.

That is, the offset distance of each of the deflected small pixlets of each of the two pixels from the pixel center of each of the pixels may be determined based on the refractive index of the microlens of each of the two pixels, the distance from the center of the image sensor to the single optical system corresponding to the image sensor, the diameter of the single optical system, and the distance from the microlens of each of the two pixels to the center of each of the two pixels, to maximize the parallax between the images acquired by the deflected small pixlets of the two pixels, assuming that the sensitivity of sensing the optical signals from the deflected small pixlets of each of the two pixels is guaranteed to be greater than or equal to the predetermined level.

Subsequently, the image sensor processes the optical signals in the deflected small pixlets of the two pixels to obtain the images through S320.

Thereafter, the depth calculator calculates the depth between the image sensor and the object using the parallax between the images input from the image sensor through S330.

Thus, in S320 to S330, the camera system may regularly use the pixlets for the depth calculation within the two pixels (using the deflected small pixlets of the two pixels) to simplify a depth calculating algorithm and reduce work complexity, to reduce depth calculation time consumption and secure real-time, to simplify circuit configuration, and to ensure consistent depth resolution.

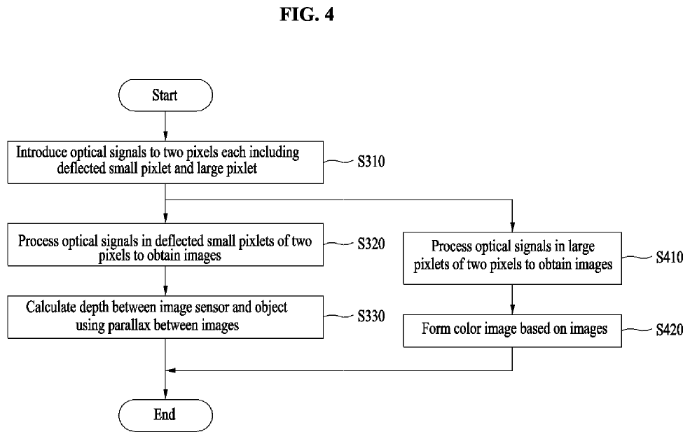

FIG. 4 is a flowchart illustrating a method of operating a camera system according to another embodiment. Hereinafter, the method of operating the camera system to be described includes all of operations S310 to S330 of the method of operating the camera system described with reference to FIG. 3, and includes additional operations S410 to S420. Accordingly, detailed descriptions of the operations S310 to S330 shown in FIG. 4 will be omitted.

Referring to FIG. 4, the image sensor included in the camera system processes the optical signals from the deflected small pixlets of the two pixels through S320 to obtain the images, and at the same time, processes the optical signals in the large pixlets of the two pixels through S410 to obtain images.

Accordingly, the image sensor forms a color image based on the images acquired in S410, through S420. Here, when forming the color image, the image sensor may further utilize not only the images acquired in S410 but also the images acquired in S320. As an example, the image sensor merges the images acquired by processing the optical signals from the deflected small pixlets of the two pixels and the images acquired by processing the optical signals from the large pixlets of the two pixels, thereby forming the color image.

Embodiments may suggest the image sensor with the complementary pixlet structure, in which the two pixlets are implemented in one pixel, to enable estimation of the depth to the object in the single camera system.

In detail, embodiments may suggest the technique in which the image sensor with the structure including the two pixels, each of which includes the deflected small pixlet deflected in one direction based on the pixel center and the large pixlet disposed adjacent to the deflected small pixlet—each pixlet includes the photodiode converting the optical signal into the electrical signal and the deflected small pixlets of the two pixels are arranged to be symmetrical to each other with respect to each pixel center within each of the two pixels—is configured, and thus the camera system including the above-described image sensor calculates the depth between the image sensor and the object using the parallax between the images acquired from the deflected small pixlets of the two pixels.

Here, embodiments may suggest the camera system regularly using the pixlets for calculating the depth within the two pixels to simplify the depth calculating algorithm and reduce work complexity, to reduce depth calculation time consumption and secure real-time, to simplify the circuit configuration, and to ensure the consistent depth resolution.

Accordingly, embodiments may suggest the camera system useful in the autonomous vehicle or various real-time depth measurement applications in which the consistency of depth resolution and real time are important.

While this disclosure includes specific example embodiments and drawings, it will be apparent to one of ordinary skill in the art that various alterations and modifications in form and details may be made in these example embodiments. For example, suitable results may be achieved if the described techniques are performed in a different order, and/or if components in a described system, architecture, device, or circuit are combined in a different manner, and/or replaced or supplemented by other components or equivalents thereof.

Accordingly, other implementations, other embodiments, and equivalents of claims are within the scope of the following claims.

What is claimed is:

1. A camera system with a complementary pixlet structure, the camera system comprising:
an image sensor configured to include two pixels, each of the two pixels including a deflected small pixlet deflected in one direction based on a pixel center and a large pixlet disposed adjacent to the deflected small pixlet, each pixlet including a photodiode converting an optical signal to an electric signal, and the deflected small pixlets of the two pixels being arranged to be symmetrical to each other with respect to each of the pixel centers within each of the two pixels, respectively; and
a depth calculator configured to receive images acquired from the deflected small pixlets of the two pixels and calculate a depth between the image sensor and an object using a parallax between the images.

2. The camera system of claim 1, wherein the deflected small pixlets of the two pixels are disposed to maximize a distance apart from each other within the two pixels.

3. The camera system of claim 2, wherein the deflected small pixlet of one of the two pixels is a left-deflected small pixlet deflected in a left direction with respect to the pixel center, and
the deflected small pixlet of the other one of the two pixels is a right-deflected small pixlet deflected in a right direction with respect to the pixel center.

4. The camera system of claim 1, wherein the deflected small pixlet of each of the two pixels is formed to be offset from the pixel center of each of the two pixels.

5. The camera system of claim 1, wherein an offset depth of the deflected small pixlet of each of the two pixels from the pixel center is determined to maximize the parallax between the images acquired from the deflected small pixlets of the two pixels, assuming that sensitivity of sensing the optical signals in the deflected small pixlets of the two pixels is guaranteed to be greater than or equal to a predetermined level.

6. The camera system of claim 1, wherein an offset depth of the deflected small pixlet of each of the two pixels from the pixel center is determined based on a refractive index of a microlens of each of the two pixels, a distance from a center of the image sensor to a single optical system corresponding to the image sensor, a diameter of the single optical system, and a distance from the microlens of each of the two pixels to each pixel center of each of the two pixels.

7. The camera system of claim 6, wherein the offset distance “0” of the deflected small pixlet of each of the two pixels from the pixel center is determined within a range of Equation 1 below,
$$a \frac{h D}{n f} \leq O \leq b \frac{h D}{n f} \qquad Equation 1$$
herein, in Equation 1, “h” denotes a distance from the microlens of each of the two pixels to each pixel center, “D” denotes a diameter of the single optical system corresponding to the image sensor, and “n” denotes the refractive index of the microlens of each of the two pixels, and “f” denotes a distance from the center of the image sensor to the single optical system corresponding to the image sensor, and
wherein “a” and “b” are constants that satisfy Equation 2 below.
0.2≤a, b≤0.47 Equation 2

8. The camera system of claim 1, wherein the image sensor is configured to form a color image based on images acquired from the large pixlets of the two pixels.

9. The camera system of claim 8, wherein the image sensor merges the images acquired from the deflected small pixlets of the two pixels and the images acquired from the large pixlets of the two pixels to form the color image.

10. The camera system of claim 1, further comprising:
a mask disposed on the deflected small pixlet of each of the two pixels and configured to block peripheral rays of bundle of rays introducing into each deflected small pixlet of each of the two pixels and to introduce central rays therein.

11. The camera system of claim 1, wherein each of the two pixels further includes a deep trench isolation (DTI) between the deflected small pixlet and the large pixlet.

12. The camera system of claim 1, wherein the images input to the depth calculator are not simultaneously input, but are multiplexed by pixel unit to be input.

13. The camera system of claim 12, further comprising:
a single processing device for image denoising,
wherein the multiplexed images are sequentially processed.

14. The camera system of claim 1, wherein the depth calculator does not perform image rectification for projecting the images into a common image plane.

15. A method of operating a camera system including an image sensor with a complimentary pixlet structure and a depth calculator, the method comprising:
inputting, at in the image sensor, optical signals to two pixels, each of the two pixels including a deflected small pixlet deflected in one direction based on a pixel center and a large pixlet disposed adjacent to the deflected small pixlet, each pixlet including a photodiode converting an optical signal to an electric signal and the deflected small pixlets of the two pixels being arranged to be symmetrical to each other with respect to each of pixel centers within the two pixels, respectively;
processing, at the image sensor, the optical signals through the deflected small pixlets of the two pixels to obtain images; and
calculating, at the depth calculator, a depth between the image sensor and an object using a parallax between the images input from the image sensor.

16. The method of claim 15, wherein the deflected small pixlets of the two pixels are disposed to maximize a distance apart from each other within the two pixels.

17. The method of claim 15, wherein an offset depth of the deflected small pixlet of each of the two pixels from the pixel center is determined to maximize the parallax between the images acquired from the deflected small pixlets of the two pixels, assuming that sensitivity of sensing the optical signals in the deflected small pixlets of the two pixels is guaranteed to be greater than or equal to a predetermined level.

18. The method of claim 15, wherein an offset depth of the deflected small pixlet of each of the two pixels from the pixel center is determined based on a refractive index of a microlens of each of the two pixels, a distance from a center of the image sensor to a single optical system corresponding to the image sensor, a diameter of the single optical system, and a distance from the microlens of each of the two pixels to each pixel center of each of the two pixels.
